(19) United States
(12) Patent Application Publication
(10) Pub. No.: US 2007/0151711 A1
(43) Pub. Date: Jul. 5, 2007

(54) Heat sink and method for manufacturing the same

(75) Inventors: Kuo-Hsin Chen, Jhonghe City (TW); Hsuan-Chih Lin, Jhonghe City (TW)

Correspondence Address: HDSL, 4331 STEVENS BATTLE LANE, FAIRFAX, VA, 22033, US

(73) Assignees: Kuo-Hsin Chen; Hsuan-Chih Lin; Hoff Thermal Solution Co., Ltd

(21) Appl. No.: 11/325,543

(22) Filed: Jan. 5, 2006

(51) Int. Cl. H05K 7/20; B23P 6/00

(52) U.S. Cl. 165/104.33; 29/890.032; 361/700

(57) ABSTRACT

A heat sink and a method for manufacturing the same. The heat sink is used to contact on a heat-generating source of an electronic device. The heat sink comprises a heat-conducting member and at least one heat pipe. With the bottom edge of a heat-absorbing end of the heat pipe contacting with the surface of the heat-generating source, and with the tight connection between the heat pipe and the heat-conducting member, the heat-conducting rate and the heat-dissipating performance of the heat sink can be greatly increase.

### BACKGROUND OF THE INVENTION

1. Field of the Invention

The present invention relates to a heat sink and a method for manufacturing the same. In particular, the present invention relates to a heat sink able to contact on a heat-generating source of an electronic device.

2. Description of Related Art

Recently, in order to dissipate the heat generated by the electronic elements, heat pipes are mainly used in the electronic industry due to their high heat-conducting capability, high heat-conducting rate, low weight, simple structure and versatility. Therefore, the heat pipes can conduct a great amount of heat without consuming too much electricity, and thus are very suitable for dissipating heat of the electronic products. Further, the tight combination of the heat pipe and a heat-conducting member has direct influence on the heat-conducting rate and the heat-dissipating performance of a heat sink. Thus, it has become an important issue for the electronic industry to improve the tightness between the heat pipe and the heat-conducting element.

A conventional structure of a heat sink mainly comprises a heat-conducting block, at least one heat pipe and a plurality of heat-dissipating pieces. The top surface of the plate-like heat-conducting block made of copper is coated with a heat-conducting medium. Then, one end of the heat pipe is provided on the surface of the heat-conductive block on which the heat-conductive medium is coated. The heat pipe is welded to the heat-conducting block by heating and melting. Finally, each heat-dissipating piece is orderly stacked on the heat pipe one by one. As a result, a heat sink having heat pipes can be obtained.

However, the above conventional structure of heat sink still has some problems when it is used in practice. Since the path for conducting the heat is from the heat-conducting block to the heat pipe, the heat-conducting rate of the heat pipe is generally several times larger than that of the copper heat-conducting block. As a result, the rapid heat-conducting rate of the heat pipe cannot be efficiently exhibited. Further, the heat conduction between the heat-conducting block and the heat pipe still needs the conduction of the heat-conducting medium. The heat-conducting medium is often made by solder paste in consideration of cost and other practical conditions. However, the heat-conducting coefficient of the solder material is smaller than that of the copper material. As a result, the heat-conducting rate will be further reduced. According to the above, the heat-conducting rate of the foregoing structure of the heat sink is greatly restricted, and thus the heat-conducting rate and the heat-dissipating performance of the whole heat sink are greatly reduced.

In view of the drawbacks of conventional art, the inventor of the present invention thus proposed an improved heat sink and the method for manufacturing the same based on his expert experiences in this field.

### SUMMARY OF THE INVENTION

The present invention is to provide a heat sink and a method for manufacturing the same. With the bottom edge of the heat-absorbing end of the heat pipe contacting with a surface of the heat-generating source, and with the tight connection between the heat pipe and the heat-conducting member, the heat-conducting rate and the heat-dissipating performance of the heat sink can be greatly increased.

Accordingly, the present invention provides a heat sink able to contact on a heat-generating source of an electronic device, comprising:

a heat-conducting member comprising a base a cover connected to the upside of the base, wherein at least one non-opening grooves are provided on the base, the center of each non-opening groove is formed with a through hole, and the cover is provided with a through hole corresponding to the end of the non-opening groove; and

at least one heat pipe having a heat-absorbing end and a heat-dissipating end, wherein the heat-dissipating end penetrates into the hole of the cover, and the heat-absorbing end is connected between the base and the cover via a heat-conducting medium.

Furthermore, the present invention provides a method for manufacturing the heat sink, comprising the steps of:
a) preparing the heat sink material, wherein one end of the heat pipe penetrates the through hole of the cover, and is correspondingly connected on the base, such that the other end of the heat pipe is accommodated in the non-opening groove of the base;
b) arranging the heat-conducting member and the heat pipe on a recess region of a mold;
c) pouring the heat-conducting medium to be filled within the space formed by the heat-conducting member, the heat pipe and the mold;
d) heating the mold to melt the heat-conducting medium and thus to permeate and fill up the aforesaid space, and cooling to reduce the temperature to connect the heat-conducting member with the heat pipe; and
e) machining and treating the bottom surface of the thus-formed heat sink to become a plane.

### BRIEF DESCRIPTION OF DRAWING

FIG. 1 is an exploded perspective view of the present invention;

FIG. 2 is a schematic view showing the assembling of the present invention;

FIG. 3 is a schematic view showing the state in which the present invention shown in FIG. 2 is filled with the heat-conducting medium;

FIG. 4 is a schematic view showing the assembling of the present invention seen from another view angle;

FIG. 5 is a schematic view showing a state in which the present invention is connected with a heat-dissipating piece set and a fan frame;

FIG. 6 is a schematic view showing a state in which the present invention is applied to a heat-generating source;

FIG. 7 is an exploded perspective view showing a state in which the heat pipe of the present invention penetrates the cover and the base;

FIG. 8 is a cross-sectional view showing a state in which the heat pipe and the heat-conducting member of the present invention are provided on the mold and the heat-conducting medium is poured; and

FIG. 9 is a partial enlarged cross-sectional view showing a state in which the present invention has been removed from the mold and machined.

### DETAILED DESCRIPTION OF THE INVENTION

The characteristics and technical contents of the present invention will be explained with reference to the following detailed description and accompanying drawings. It should be understood that the drawings are illustrative examples only, but not intended to limit the scope of the present invention.

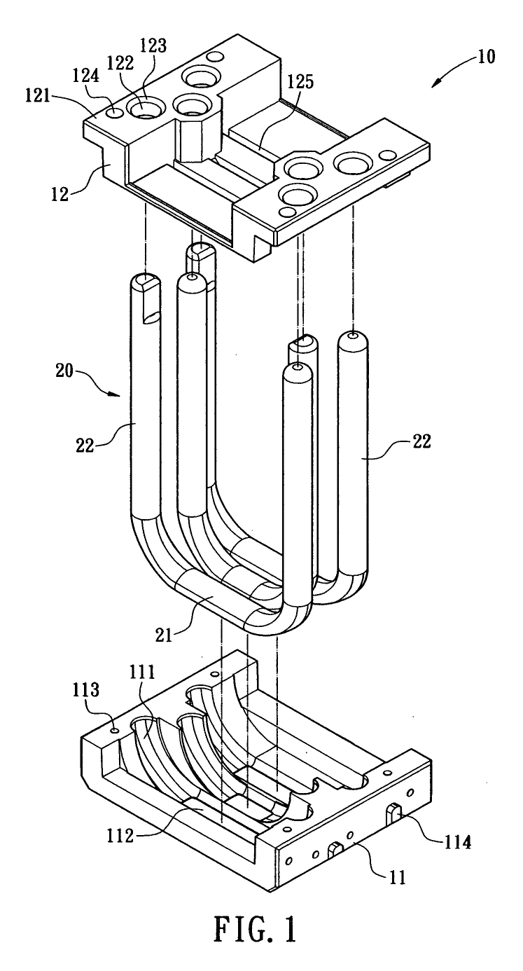

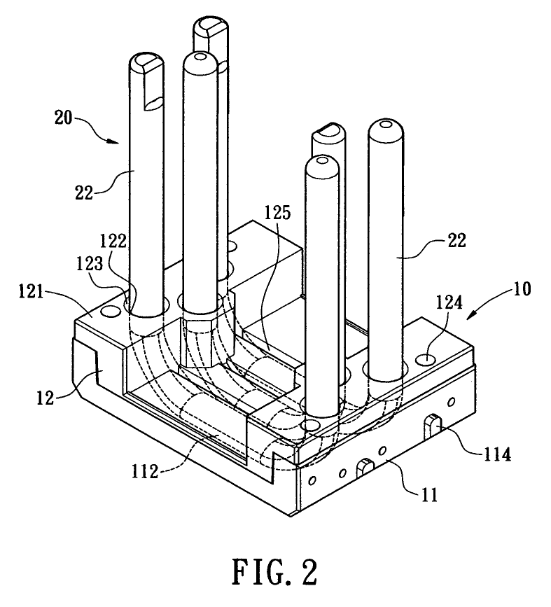

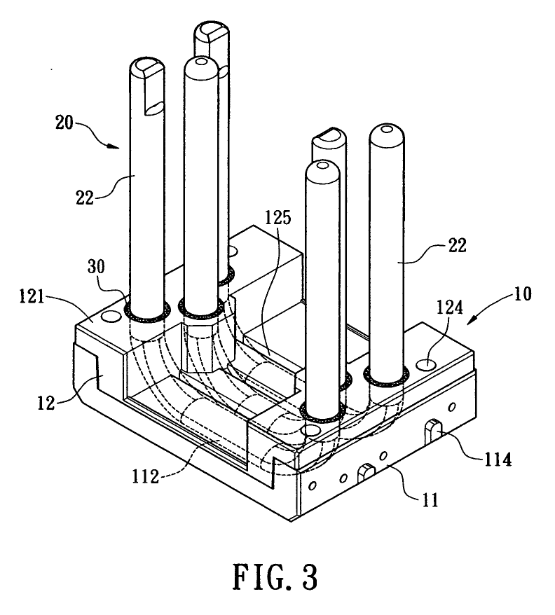

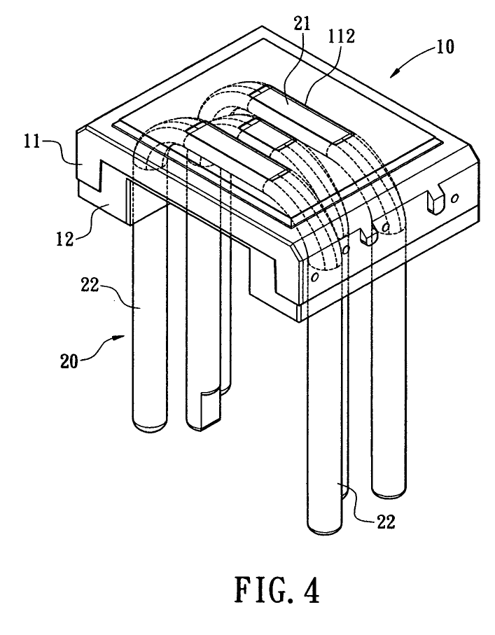

FIG. 1 is an exploded perspective view of the present invention. FIG. 2 is a schematic view showing the assembling of the present invention. FIG. 3 is a schematic view showing the state in which the heat sink of the present invention shown in FIG. 2 is filled with the heat-conducting medium. FIG. 4 is a schematic view showing the assembling of the present invention seen from another view angle. The present invention provides a heat sink mainly comprising a heat-conducting member 10 and at least one heat pipe 20.

The heat-conducting member 10 comprises a base 11 and a cover 12 connected to the upside of the base 11. The base 11 can be made of copper, aluminum or other materials having good heat conductivity. The base 11 is formed into a near “␣” shape. The base 11 is provided with at least one non-opening grooves 111. In the present embodiment, three non-opening grooves 111 parallel to one another are used. The center of each non-opening groove 111 is provided with a through hole 112. The top faces of two side plates of the base 11 are provided with a plurality of connecting hole 113, respectively. The connecting holes 113 can be screw holes or general holes. The outside faces of the two side plates of the base 11 are provided with a plurality of protruding blocks 114. The cover 12 can be made of copper, aluminum or other materials having good heat conductivity. The cover 12 is provided to correspond to the base 11, and is also formed into a near “␣” shape. The top ends of the left and right side plates of the cover are provided with horizontally extending plates 121, respectively. The plate 121 is provided with a plurality of through holes 122 corresponding to the left and right ends of each non-opening groove 111 of the base 11. The top edges of the through holes 122 are provided with chamfering angles 123. The front and rear ends of the plate are provided with positioning holes 124 corresponding to the connecting holes 113. Further, the bottom plate of the cover 12 is provided with a plurality of parallel grooves 125 corresponding to the interval of each though hole 122.

The number of the heat pipe 20 fully depends on the amount of the heat generated by the heat-generating source. In the present embodiment, three heat pipes are used. The heat pipes 20 can be U-shaped circular pipes, U-shaped oval pipes, U-shaped rectangular pipes (isothermal plate) or other constructions having different geometric shapes. The heat pipe has a heat-absorbing end 21 and two heat-dissipating ends 22. The heat-dissipating ends 22 penetrate the through holes 122 of the cover 12, and the heat-absorbing end 21 is connected between the base 11 and the cover 12 via the heat-conducting medium. Further, each bottom edge of the base 11 and the heat pipe 20 are in the same plane.

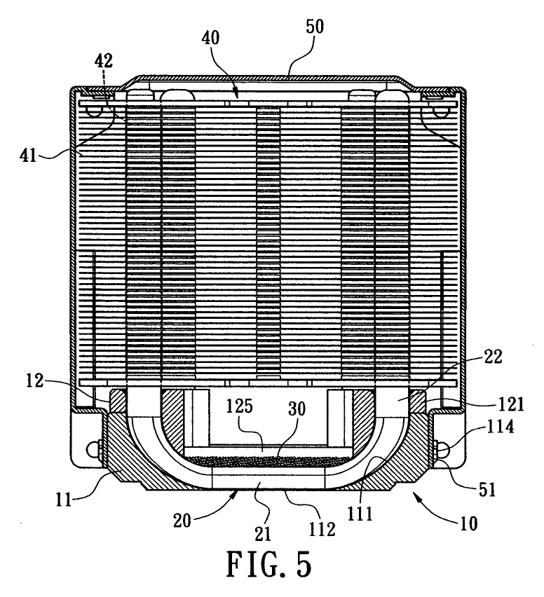

FIG. 5 is a schematic view showing a state in which the present invention is connected with a heat-dissipating piece set and a fan frame. The heat sink of the present invention further comprises a heat-dissipating piece set 40. The heat-dissipating piece set 40 is made of a plurality of stacking heat-dissipating pieces 41. A through hole 42 is provided on each heat-dissipating piece 41 to correspond to the same line. The through hole 42 can be inserted and connected by the heat-dissipating end 22 of each heat pipe 20. Further, a fan frame 50 is peripherally covered in the exterior of the heat pipes 20 and the heat-dissipating piece set 40. The bottom of the fan frame 50 is recessed inwardly with fixing plates 51. A hole is provided on each fixing plate 51 to correspond to the protruding block 114 of the base 11, thereby to fixedly connect to the base 11.

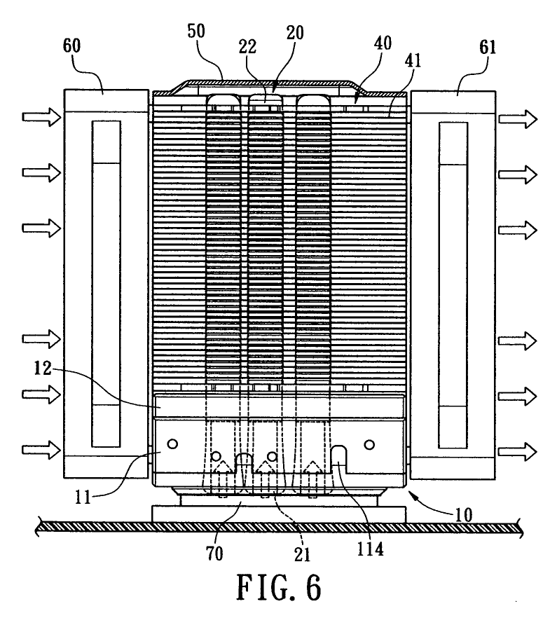

FIG. 6 is a schematic view showing a state in which the present invention is applied to a heat-generating source. A first fan 60 and a second fan 61 can be provided on the front and rear sides of the fan frame 50. Further, the heat sink of the present invention is arranged on a heat-generating source 70 (e.g. CPU).. When the heat-generating source 70 is in operation, it produces a great amount of heat. The heat can be directly conducted from the surface of the heat-generating source 70 to the heat-absorbing end 21 of each heat pipe 20 and base 11. Further, with the vapor-liquid-phase heat-conducting means within each heat pipe 20 and the heat conduction of the heat-conducting member 10, the heat can be rapidly conducted out. With the heat conduction and diffusion of the heat-dissipating piece set 40 connected in series to each heat pipe 20, and the forced blow of each fan 61, 62, the performance and efficiency in dissipating heat can be greatly increased.

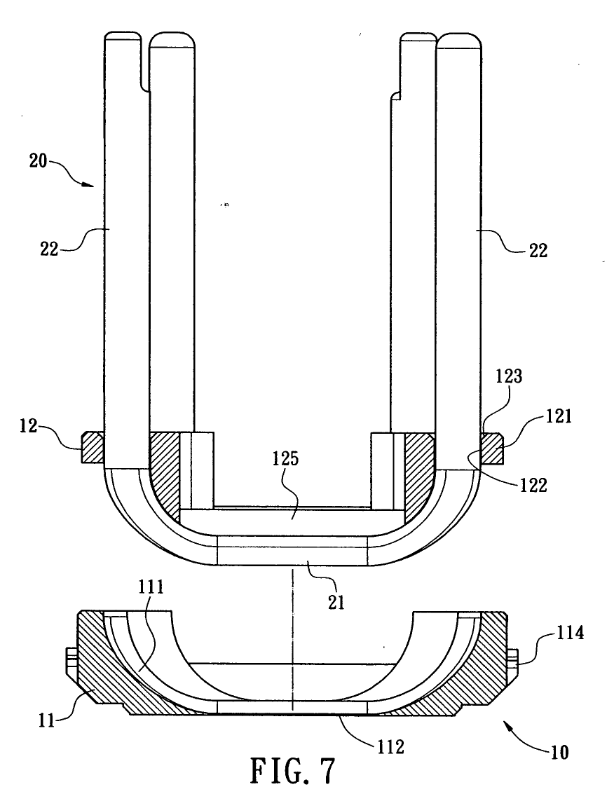

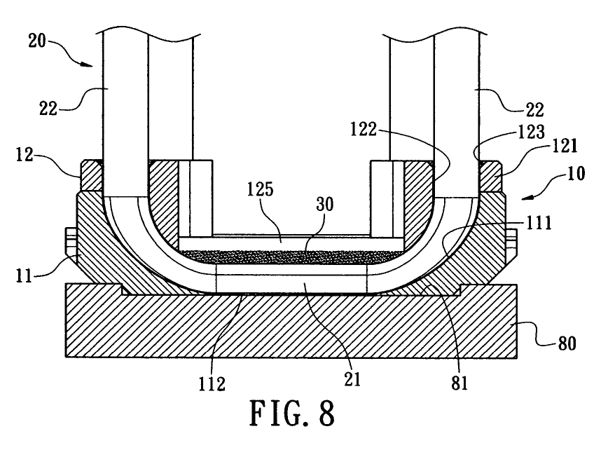

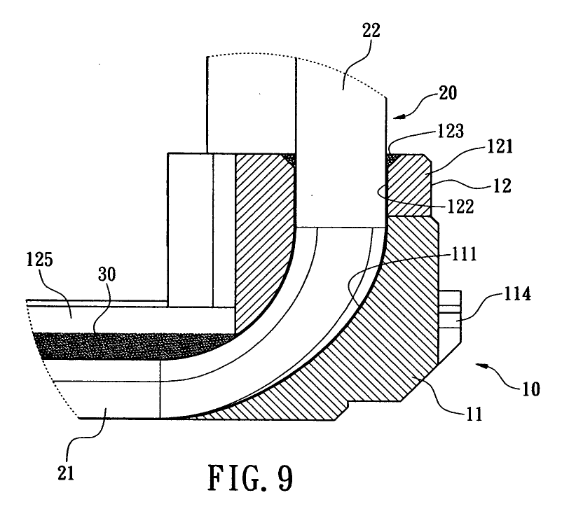

FIG. 7 is an exploded perspective view showing a state in which the heat pipe of the present invention penetrates the cover and the base. FIG. 8 is a cross-sectional view showing a state in which the heat pipe of the present invention and the heat-conducting member are provided on the mold and the heat-conducting medium is poured. FIG. 9 is a partial enlarged cross-sectional view showing a state in which the present invention has been removed from the mold and machined. The present invention provides a method for manufacturing the heat sink, comprising the steps of:
a) Preparing the heat sink material, wherein one end of the heat pipe 20 penetrates the through hole 122 of the cover 12, and is correspondingly connected on the base 11, such that the other end of the heat pipe 20 is accommodated in the non-opening groove 111 of the base 11. In this step, the outer and inner sides of the heat-absorbing end 21 of the heat pipe 20 are coated with the heat-conducting medium 30, respectively. Both heat-dissipating ends 22 of the heat pipe 20 upwardly penetrate the through holes 122 of the cover 12 from the bottom of the heat-conducting member 10. The heat-absorbing end 21 of the heat pipe 20 and the bottom of the cover 12 are inserted into the non-opening groove 12 of the base 11. The shape of the periphery of the non-opening groove 12 corresponds to that of the bottom edge of the heat-absorbing end 21 of the heat pipe 20, such that the heat pipe 20 can abut against the base 11 and contact with each other (as shown in FIG. 8)
b) Arranging the heat-conducting member 10 and the heat pipe 20 on a recess region 81 of a mold 80. In this step, since the recess region 81 of the mold 80 (as shown in FIG. 8) is provided to correspond to the shape of the bottom of the base 11, the base 11 is provided on the upside of the mold 80, such that the bottom surface of the base 11 can abut against the surface of the recess region 81 of the mold 80.
c) Pouring the heat-conducting medium 30 to be filled within the space formed by the heat-conducting member 10, the heat pipe 20 and the mold 80. In this step, the heat-conducting medium 30 can be made of the solder paste. The heat-conducting medium 30 can be poured from the through hole 122 of the cover 12 and the upside of the groove 125 by extrusion. Further, the chamfering angle 123 of the through hole 122 facilitates the heat-conducting medium 30 to easily pour into the space formed by the heat-conducting member 10, the heat pipe 20 and the recess region 81 of the mold 80. Moreover, the heat-conducting medium 30 is filled with the chamfering angle 123 of the through hole 122 of the cover 12, thereby to supplement the molten heat-conducting medium 30.
d) Heating the mold 80 to melt the heat-conducting medium 30 and thus to permeate and fill up the aforesaid space, and cooling to reduce the temperature to connect the heat-conducting member 10 with the heat pipe 20. In this step, the heat-conducting member 10, the heat pipe 20 and the mold 80 poured with the heat-conducting medium 30 are conveyed into a heating furnace, such that the heat-conducting medium 30 can uniformly permeate and fill up the apertures or seams among the base 11, the cover 12 and the heat pipe 20. Although the heat-conducting medium 30 has been expanded after being heated, the liquid-phase fluid of the heat-conducting medium 30 still cannot overflow due to the chamfering angle 123 of the through hole 122. The way of cooling can be carried out in room temperature. Then, the thus-formed heat sink can be removed from the mold 80.
e) Machining and treating the bottom surface of the thus-formed heat sink to become a plane. In this step, after forming, since the heat-conducting medium 30 is protruded from the bottom surface of the base 11 of the heat-conducting member 10, the bottom surface of the heat sink is then subjected to the machining and grinding by a plane grinder, emery cloth, sand paper or sand band, such that the bottom edge of the heat sink can be on the same plane. Further, the heat-conducting medium 30 glued on the bottom surface of the base 11 can be completely removed, such that each bottom edge of the base 11 and the heat pipe 20 can be on the same plane.

The method for manufacturing the heat sink of the present invention further comprises a step:
f) Connecting the heat-dissipating piece set 40 on the heat-dissipating end 22 of the heat pipe 20. In this step, after a plurality of heat-dissipating pieces 41 have been stacked to form a heat-dissipating piece set 40, the thus-formed heat-dissipating piece set 40 is then connected to the heat pipe 20. Alternatively, each heat-dissipating piece 41 can be orderly stacked one by one on the heat-dissipating end 22 of the heat pipe 20.

Therefore, with the above steps, the method for manufacturing the heat sink of the present invention can be achieved.

According to the above description, in the present invention, with the bottom edge of the heat-absorbing end 21 of the heat pipe 20 directly contacting with the surface of the heat-generating source 70 of the electronic device, and with the tight connection among the heat pipe 20, the base 11 of the heat-conducting member 10 and the cover 12, the heat-conducting rate and the heat-dissipating performance of the heat sink can be greatly increased.

According to the above, the heat sink and the method for manufacturing the same of the present invention indeed achieve desired functions with the aforesaid structure. Further, since the construction of the present invention has not been published or put to public use prior to applying for patent, the present invention involves the novelty and inventive steps, and conforms to the requirements for an invention patent.

Although the present invention has been described with reference to the foregoing preferred embodiments, it will be understood that the invention is not limited to the details thereof. Various equivalent variations and modifications can still be occurred to those skilled in this art in view of the teachings of the present invention. Thus, all such variations and equivalent modifications are also embraced within the scope of the invention as defined in the appended claims.

What is claimed is:

1. A heat sink, comprising:
a heat-conducting member comprising a base and a cover connected to the upside of the base, wherein the base is provided with at least one non-opening grooves, the center of each non-opening groove is provided with a through hole, and the cover is provided with a through hole corresponding to the end of the non-opening groove; and
at least one heat pipe having a heat-absorbing end and a heat-dissipating end, wherein the heat-dissipating end penetrates into the through hole of the cover, and the heat-absorbing end is connected between the base and the cover via a heat-conducting medium.

2. The heat sink according to claim 1, wherein the base is formed into a “␣” shape, the top faces of two side plates are provided with a plurality of connecting holes, the cover is also formed into a “␣” shape, the ends of the two side plates are horizontally extended with plates, and the plate is provided with a positioning hole corresponding to the connecting hole for inserting a fixing element.

3. The heat sink according to claim 2, wherein the outside faces of the two side plates of the base are protruded with a plurality of protruding blocks, respectively.

4. The heat sink according to claim 1, wherein the periphery of the top portion of the through hole of the cover is provided with a chamfering angle.

5. The heat sink according to claim 1, wherein the heat pipe is any one of a U-shaped circular pipe, U-shaped oval pipe or U-shaped rectangular pipe.

6. The heat sink according to claim 1, wherein the bottom edges of the base and the heat pipe are on the same plane.

7. The heat sink according to claim 1, further comprising a heat-dissipating piece set, wherein the heat-dissipating piece set has a plurality of stacked heat-dissipating pieces, each heat-dissipating piece is provided with a through hole corresponding to the heat-dissipating end of the heat pipe, and the heat-dissipating end of the heat pipe penetrates into the through hole of the each heat-dissipating piece.

8. A method for manufacturing the heat sink, comprising the steps of:
preparing the heat sink material, wherein one end of the heat pipe penetrates the through hole of the cover, and is correspondingly connected on the base, such that the other end of the heat pipe is accommodated in the non-opening groove of the base;
arranging the heat-conducting member and the heat pipe on a recess region of a mold;
pouring the heat-conducting medium to be filled within the space formed by the heat-conducting member, the heat pipe and the mold;
heating the mold to melt the heat-conducting medium and thus to permeate and fill up the aforesaid space, and cooling to reduce the temperature to connect the heat-conducting member with the heat pipe; and
machining and treating the bottom surface of the thus-formed heat sink to become a plane.

9. The method for manufacturing the heat sink according to claim 8, wherein the heat-conducting medium is poured by extrusion.

10. The method for manufacturing the heat sink according to claim 8, wherein the way of heating is carried out by heating in a furnace.

11. The method for manufacturing the heat sink according to claim 8, wherein the way of cooling is carried out by cooling in room temperature.

12. The method for manufacturing the heat sink according to claim 8, wherein the way of machining is carried out by grinding with any one of a grinder, emery cloth, sand paper or sand band.

13. The method for manufacturing the heat sink according to claim 8, further comprising connecting the heat-dissipating piece set on the heat-dissipating end of the heat pipe.
